(19) United States
(12) Patent Application Publication
(10) Pub. No.: US 2006/0148129 A1
(43) Pub. Date: Jul. 6, 2006

(54) Silicon direct bonding method

(76) Inventors: Seung-mo Lim, Suwon-si (KR); Hwa-sun Lee, Suwon-si (KR); Jae-chang Lee, Hwaseong-si (KR); Jae-woo Chung, Suwon-si (KR); Woon-bae Kim, Suwon-si (KR)

Correspondence Address: LEE & MORSE, P.C.;Attorneys and Counselors At Law, SUITE 2000, 1101 WILSON BOULEVARD, ARLINGTON, VA, 22209, US

(21) Appl. No.: 11/325,464

(22) Filed: Jan. 5, 2006

(30) Foreign Application Priority Data
Jan. 5, 2005 (KR) 10-2005-0000831

(51) Int. Cl. H01L 21/50; H01L 21/30

(52) U.S. Cl. 438/106; 438/455; 438/458

(57) ABSTRACT

A silicon direct bonding method including preparing two silicon substrates having corresponding bonding surfaces, forming a trench in at least one bonding surface of the two silicon substrates, and thermally bonding the two silicon substrates to one another. The trench may be along a dicing line. The trench may communicate with an outer edge of the bonded substrates.

### BACKGROUND OF THE INVENTION

1. Field of the Invention

The present invention relates to a silicon direct bonding method. More particularly, the present invention relates to a silicon direct bonding method by which void formation caused by gases is suppressed.

2. Description of the Related Art

Typically, a silicon substrate called a ‘wafer’ is used to manufacture semiconductor devices. For example, various semiconductor devices may be formed through micromachining, processing, etc., including, e.g., forming a predetermined material layer on the silicon substrate, etching a surface of the silicon substrate, etc.

In manufacturing a semiconductor device, two silicon substrates may be bonded to each other. One method of bonding is silicon direct bonding (SDB), which has been generally applied to bonding silicon substrates. Generally, the SDB method may include the following operations. After two silicon substrates are prepared, the substrates are cleaned and a thin film of ions and/or molecules, e.g., OH⁻, H⁺, H₂O, H₂, O₂, etc., is formed on the bonding surfaces of the two substrates. The two substrates are then put in close contact with one another, which results in the substrates becoming attached to each other. In detail, the two substrates are attached due to the power of the Van der Waals force existing between the ions/molecules on the opposing substrates. This Van der Waals force serves to maintain the substrates in position, i.e., they are pre-bonded by it. If the two pre-bonded substrates are then subjected to a thermal bonding process, e.g., by being put into a thermal treatment furnace and heated up to approximately 1000° C., the two substrates may be strongly bonded due to interdiffusion between atoms of the two opposing substrates.

In the SDB process just described, gases may be generated during the thermal bonding process by the ions/molecules that exist between the two substrates. The gases may not be completely discharged and may remain to cause voids at the junction of the two substrates. The voids may decrease bond strength between two silicon substrates and may elevate the defect rate of the resultant bonded semiconductor devices, detrimentally affecting yield. Moreover, the void problem may become more significant as substrate sizes increases and the bonding areas increase accordingly.

### SUMMARY OF THE INVENTION

The present invention is therefore directed to a SDB method by which void formation caused by gases is suppressed, which substantially overcomes one or more of the problems due to the limitations and disadvantages of the related art.

It is therefore a feature of an embodiment of the present invention to provide a SDB method in which a trench is formed on one or more bonding surfaces of the opposing silicon substrates, so that gases generated during a thermal treatment process may be discharged, thereby reducing or eliminating void formation caused by the gases.

It is therefore another feature of an embodiment of the present invention to provide a SDB method in which a trench is formed along a dicing line used to singulate the bonded substrates.

At least one of the above and other features and advantages of the present invention may be realized by providing a silicon direct bonding method including preparing two silicon substrates having corresponding bonding surfaces, forming a trench in at least one bonding surface of the two silicon substrates, and thermally bonding the two silicon substrates to one another.

The method may further include cleaning the two silicon substrates after forming the trench. A silicon oxide film may be formed on at least one surface of the two silicon substrates, and the trench may be formed in the silicon oxide film. The trench may be formed along at least a part of a plurality of dicing lines.

The dicing lines may include a first plurality of lines that extend in a first direction and a second plurality of lines that extend in a second direction perpendicular to the first direction. The method may further include forming a plurality of trenches along one or both of the first and second plurality of lines.

The trench may extend to the outer edge of the substrate. The trench may be formed to a predetermined depth. Forming the trench may include etching. Forming the trench may further include depositing a photoresist layer on one of the bonding surfaces, forming a pattern in the photoresist layer, and using the patterned photoresist layer as an etching mask.

At least one of the above and other features and advantages of the present invention may also be realized by providing a method of forming a bonded semiconductor structure including providing two silicon substrates, at least one of the substrates having a plurality of active devices formed thereon, forming a plurality of trenches in a bonding surface of at least one of the two silicon substrates, thermally bonding the two silicon substrates together, and singulating the bonded substrates into a plurality of bonded semiconductor structures, wherein the bonded substrates are singulated along dicing lines, and the plurality of trenches corresponds to the dicing lines.

Thermally bonding the two silicon substrates together may form a bonded substrate structure, the bonded substrate structure including a plurality of channels at an interface of the two silicon substrates, the plurality of channels corresponding to the plurality of trenches. The plurality of channels may communicate to a circumferential edge of the bonded substrate structure. The plurality of trenches may include first trenches formed in a first direction and second trenches formed in a second direction perpendicular to the first direction, the second trenches intersecting the first trenches. The method may further include, before thermally bonding, applying a thin film to bonding surfaces of the two silicon substrates, the thin film including one or more of OH⁻ ions, H⁺ ions, H₂O molecules, H₂ molecules and O₂ molecules.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A-1E illustrate cross-sectional views of stages in a method of bonding two substrates according to a first embodiment of the present invention;

FIG. 2 illustrates a perspective view of a trench formed on a bonding surface of a substrate according to the first embodiment of the present invention;

FIGS. 3A-3C illustrate cross-sectional views of stages in a method of bonding two substrates according to a second embodiment of the present invention; and

FIG. 4 illustrates a perspective view of a trench formed on a bonding surface of a substrate according to the second embodiment of the present invention.

### DETAILED DESCRIPTION OF THE INVENTION

Korean Patent Application No. 10-2005-0000831, filed on Jan. 5, 2005, in the Korean Intellectual Property Office, and entitled: “Silicon Direct Bonding Method,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

In the SDB method according to the present invention, gases generated during a thermal treatment process may be discharged through one or more trenches existing at the interface of opposing silicon substrates, so that void formation at the interface may be prevented or minimized.

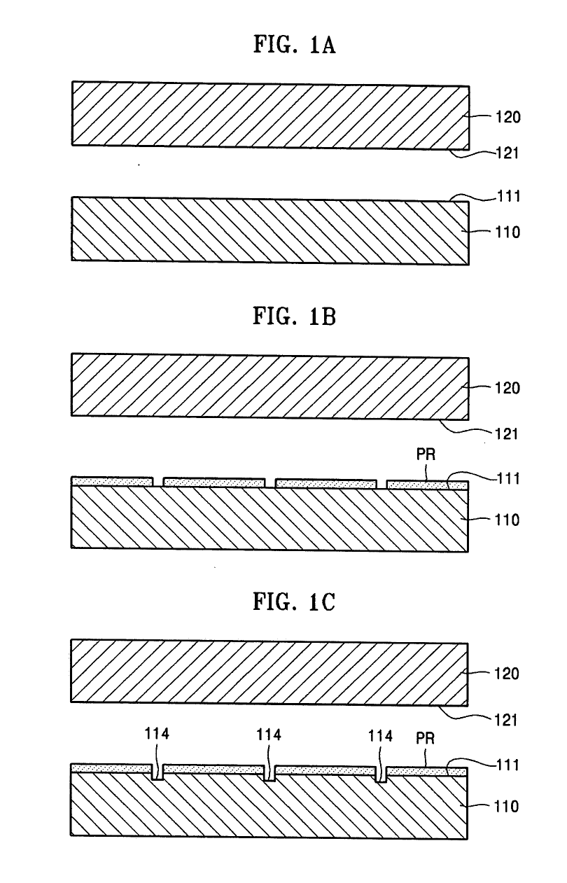

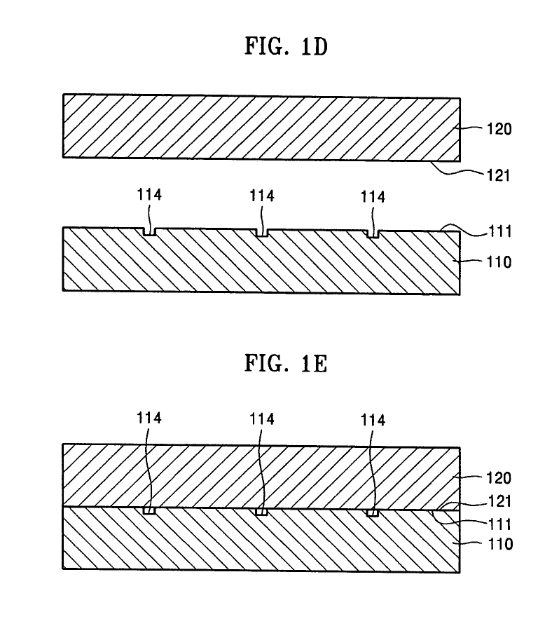

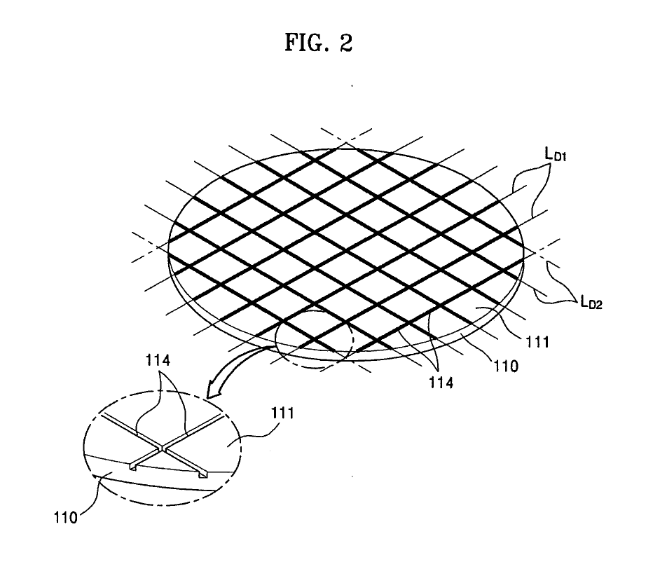

FIGS. 1A-1E illustrate cross-sectional views of stages in a method of bonding two substrates according to a first embodiment of the present invention, and FIG. 2 illustrates a perspective view of a trench formed on a bonding surface of a substrate according to the first embodiment of the present invention. Referring to FIG. 1A, a SDB method according to the first embodiment of the present invention may be used to bond first and second substrates 110, 120. The first and second substrates 110, 120 may be, e.g., silicon substrates. The first and second silicon substrates 110, 120 may be a type of silicon wafer commonly used in the manufacture of semiconductor device. The first silicon substrate 110 may include a first bonding surface 111 and the second silicon substrate 120 may include a second bonding surface 121 corresponding to the first bonding surface 111.

Referring to FIG. 1B, a photoresist PR may be coated on one of the first and second silicon substrates 110 and 120. As illustrated, the PR is coated on the first bonding surface 111 of the first silicon substrate 110. Subsequently, the PR may be patterned in a predetermined pattern through an exposure and development process to expose a part of the first bonding surface 111.

Referring to FIG. 1C, the first bonding surface 111 may be etched to a predetermined depth, using the PR as an etching mask, thereby forming one or more trenches 114. Etching of the first bonding surface 111 may be performed by, e.g., dry etching using a method such as reactive ion etching (RIE), a wet etching method, etc. After etching, the PR may be stripped, leaving the trench 114 formed in the first bonding surface 111, as shown in FIG. 1D.

In the above-described operations, it will be appreciated that the trench may be formed in the second substrate 120, or in both the first and second substrates 110, 120, and that the above-described operations are merely exemplary. Further, a cross-sectional shape of the trenches, while shown as being rectangular, may be any shape, particularly in accordance with a formation process of the trenches.

Referring to FIG. 2, the trench 114 may be formed along a plurality of dicing lines L_{D1} and L_{D2}, in order not to affect semiconductor devices formed on the silicon substrates 110, 120. As used herein, dicing refers to singulation of the substrates, wherein a plurality of semiconductor devices formed on the two silicon substrates 110, 120 are separated into individual dies by, e.g., cutting. The dicing lines L_{D1} and L_{D2} may include first lines L_{D1} that extend in a first direction and second lines L_{D2} that extend in a second direction perpendicular to the first direction. A plurality of trenches 114 may be formed along the first lines L_{D1} and the second lines L_{D2}, as shown in FIG. 2. Alternatively, trenches 114 may be formed along only one of the first lines L_{D1} and the second lines L_{D2}.

The trenches 114 may be formed to extend to the circumference of the two silicon substrates 110, 120 and may communicate to the outside of the silicon substrates 110, 120. Thus, gases generated between the silicon substrates 110, 120 may be discharged to the outside of the silicon substrates 110, 120, as will be described in further detail below.

The first silicon substrate 110 and the second silicon substrate 120 may be cleaned (not shown) after forming the trenches 114. The cleaning operation may include, e.g., a cleaning process and a drying process.

A thin film (not shown) may be formed on the first bonding surface 111 of the first silicon substrate 110 and on the second bonding surface 121 of the second silicon substrate 120. The thin film may include, e.g., ions and/or molecules such as OH⁻, H⁺, H₂O, H₂ and O₂, etc.

Referring to FIG. 1E, bonding surfaces 111, 121 of the first and second silicon substrates 110, 120 may be brought into close contact with one another, such that the two silicon substrates 110, 120 are pre-bonded by Van der Waals forces between the above-described ions/molecules. The two silicon substrates 110, 120 in the pre-bonded state may then be thermally bonded. Thermal bonding may include, e.g., putting the pre-bonded substrates 110, 120 into a thermal treatment furnace and thermally heating to approximately 1000° C. Thus, the two silicon substrates 110 and 120 may strongly bonded due to interdiffusion between atoms of the two silicon substrates 110, 120.

During thermal bonding, gases may be generated by ions/molecules existing at the interface between the two silicon substrates 110, 120. According to the present invention, the gases may flow into the trench 114, and may flow through the trench 114 to be smoothly discharged to the outside of the silicon substrates 110, 120. The gases may exit the trench 114 at the circumferential edge of the silicon substrates 110, 120.

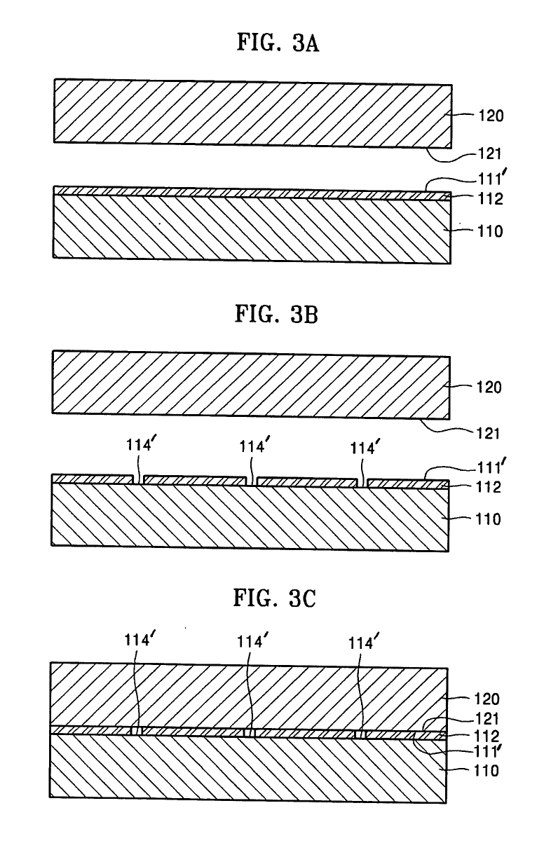

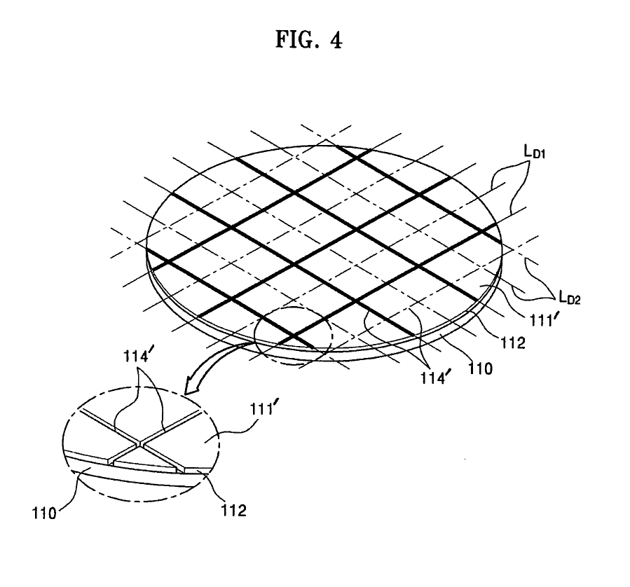

FIGS. 3A-3C illustrate cross-sectional views of stages in a method of bonding two substrates according to a second embodiment of the present invention, and FIG. 4 illustrates a perspective view of a trench formed on a bonding surface of a substrate according to the second embodiment of the present invention. Referring to FIG. 3A, in the SDB method according to the second embodiment of the present invention, a silicon oxide film 112 may be formed on one of two silicon substrates 110, 120. As illustrated, the silicon oxide film 112 is formed on the surface of the first silicon substrate 110. The surface of the silicon oxide film 112 may serve as a first bonding surface 111′. It will be appreciated that the silicon oxide film 112 may also be formed on the second silicon substrate 120, or on both the first and second silicon substrates 110, 120. If the silicon oxide film 112 is formed on one or both of the silicon substrates 110, 120, the bond strength between the two silicon substrates 110, 120 may be enhanced.

Referring to FIG. 3B, the silicon oxide film 112 formed on the first silicon substrate 110 may be etched to a predetermined depth, thereby forming a trench 114′. The formation of the trench 114′ may be performed as described above with respect to FIGS. 1B and 1C. The trench 114′ may be formed to penetrate the entire thickness of the silicon oxide film 112, as shown in FIG. 3B, or may be formed to a depth that is less than the thickness of the silicon oxide film 112 (not shown).

Referring to FIG. 4, the trench 114′ can be formed along all or part of dicing lines L_{D1}, L_{D2}. The trench 114′ may also be formed in various other configurations suitable to allow gases to be smoothly discharged from the bonding area of the silicon substrates 110, 120. The trench 114′ may be formed to extend to the circumference of the two silicon substrates 110, 120 and may communicate with the outside of the silicon substrates 110, 120 via a circumferential edge thereof.

The first and second silicon substrates 110, 120 may be cleaned, a film of ions/molecules may be applied, and, as shown in FIG. 3C, the first and second silicon substrates 110, 120 may be brought into close contact with one another. The first and second silicon substrates 110, 120, in the closely-contacted state, may then be subjected to a thermal bonding process by, e.g., being put into a thermal treatment furnace and thermally heated to approximately 1000° C. Thus, the first and second silicon substrates 110, 120 may be bonded by interdiffusion of atoms between the first and second silicon substrates 110, 120.

During thermal treatment, gases generated by ions/molecules that exist at the interface between the first and second silicon substrates 110, 120 may be discharged through the trench 114′ to the outside of the silicon substrates 110, 120 in a similar fashion to that described above with respect to the first embodiment.

As described above, in the SDB method according to the present invention, a trench may be formed on one or more bonding surfaces of the two substrates to be bonded, such that gases generated during thermal treatment may be smoothly discharged. Thus, void formation may be reduced or eliminated at the junctions of the two bonded substrates. Accordingly, the bond strength of the two substrates may be enhanced, defect rates lowered, and yields improved.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A silicon direct bonding method, comprising:
preparing two silicon substrates having corresponding bonding surfaces;
forming a trench in at least one bonding surface of the two silicon substrates; and
thermally bonding the two silicon substrates to one another.

2. The method as claimed in claim 1, further comprising cleaning the two silicon substrates after forming the trench.

3. The method as claimed in claim 1, wherein a silicon oxide film is formed on at least one surface of the two silicon substrates, and the trench is formed in the silicon oxide film.

4. The method as claimed in claim 1, wherein the trench is formed along at least a part of a plurality of dicing lines.

5. The method as claimed in claim 4, wherein the dicing lines include a first plurality of lines that extend in a first direction and a second plurality of lines that extend in a second direction perpendicular to the first direction, the method further comprising forming a plurality of trenches along one of the first and second plurality of lines.

6. The method as claimed in claim 4, wherein the dicing lines include a first plurality of lines that extend in a first direction and a second plurality of lines that extend in a second direction perpendicular to the first direction, the method further comprising forming a plurality of trenches along both the first and second pluralities of lines.

7. The method as claimed in claim 1, wherein the trench extends to the outer edge of the substrate.

8. The method as claimed in claim 1, wherein the trench is formed to a predetermined depth.

9. The method as claimed in claim 8, wherein forming the trench includes etching.

10. The method as claimed in claim 9, wherein forming the trench further includes depositing a photoresist layer on one of the bonding surfaces, forming a pattern in the photoresist layer, and using the patterned photoresist layer as an etching mask.

11. A method of forming a bonded semiconductor structure, comprising:
providing two silicon substrates, at least one of the substrates having a plurality of active devices formed thereon;
forming a plurality of trenches in a bonding surface of at least one of the two silicon substrates;
thermally bonding the two silicon substrates together; and
singulating the bonded substrates into a plurality of bonded semiconductor structures, wherein
the bonded substrates are singulated along dicing lines, and
the plurality of trenches corresponds to the dicing lines.

12. The method as claimed in claim 11, wherein thermally bonding the two silicon substrates together forms a bonded substrate structure, the bonded substrate structure including a plurality of channels at an interface of the two silicon substrates, the plurality of channels corresponding to the plurality of trenches.

13. The method as claimed in claim 12, wherein the plurality of channels communicate to a circumferential edge of the bonded substrate structure.

14. The method as claimed in claim 11, wherein the plurality of trenches includes first trenches formed in a first direction and second trenches formed in a second direction perpendicular to the first direction, the second trenches intersecting the first trenches.

15. The method as claimed in claim 11, further comprising, before thermally bonding, applying a thin film to bonding surfaces of the two silicon substrates, the thin film including one or more of OH⁻ ions, H⁺ ions, H₂O molecules, H₂ molecules and O₂ molecules.
